(19) United States
(12) Patent Application Publication
(10) Pub. No.: US 2009/0142624 A1
(43) Pub. Date: Jun. 4, 2009

(54) MAGNETIC RECORDING MEDIUM AND A METHOD OF PRODUCING THE SAME

(75) Inventors: Hideaki TAKAHOSHI, Higashine (JP); Hisato Shibata, Higashine (JP); Shinya Sato, Higashine (JP); Isatake Kaitsu, Higashine (JP); Akira Kikuchi, Higashine (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/325,145

(22) Filed: Nov. 29, 2008

(30) Foreign Application Priority Data
Nov. 29, 2007 (JP) 2007-309442

(51) Int. Cl. G11B 5/706; C23C 14/34

(52) U.S. Cl. 428/846.6; 204/192.15

(57) ABSTRACT

A method of producing a magnetic recording medium produces a medium having a magnetic recording layer disposed above a nonmagnetic intermediate layer, The nonmagnetic intermediate layer is formed by a sputtering using a target made of an oxide material. Oxygen gas or carbon dioxide gas is supplied during the sputtering in order to suppress a state where an oxygen supply becomes insufficient due to separation of oxygen atoms from the oxide material at a time of plasma generation.

### BACKGROUND OF THE INVENTION

1. Field of the Invention

The present invention generally relates to magnetic recording media and methods of producing the same, and more particularly to a magnetic recording medium which is suited for high-density recording and to a method of producing such a magnetic recording medium.

2. Description of the Related Art

In magnetic storage apparatuses such as magnetic disk apparatuses, there are proposals to improve the recording density by employing a reproducing head which uses a tunneling type magneto-resistive element or by employing a magnetic recording medium which uses the perpendicular magnetic recording technique. In order to further improve the recording density of the magnetic recording medium, it is necessary to further reduce the medium noise. But in order to further reduce the medium noise, it is necessary to reduce the size of crystal grains forming a magnetic layer in the magnetic recording medium and to reduce the magnetic coupling between the crystal grains.

In the perpendicular magnetic recording medium which has recently been proposed, a target made of an oxide material is used when sputtering the magnetic layer to form a recording layer, in order to reduce the medium noise. By using the target made of the oxide material, an oxide is formed at grain boundaries of the magnetic grains, and it is possible to magnetically isolate the magnetic grains and reduce the medium noise.

For example, a Japanese Laid-Open Patent Application No.2004-310910 proposes a perpendicular magnetic recording medium having a recording layer made of a CoPt alloy which includes an oxide. In addition, a Japanese Laid-Open Patent Application No.2007-164826 proposes a longitudinal (or in-plane) magnetic recording medium having a recording layer with a granular structure in which CoPt ferromagnetic micro-grains are isolated by an oxide.

However, when the magnetic layer of the recording layer in the magnetic recording medium is formed by the conventional sputtering using the target which is made of the oxide material, oxygen atoms separate from the oxide material at the time of the plasma generation, to thereby introduce an oxygen loss (that is, lack of oxygen) in the recording layer. For this reason, the magnetic isolation of the magnetic grains forming the recording layer becomes insufficient, and it becomes difficult to reduce the medium noise.

### SUMMARY OF THE INVENTION

Accordingly, it is a general object of the present invention to provide a novel and useful in which the problems described above are suppressed.

Another and more specific object of the present invention is to provide a magnetic recording medium capable of reducing medium noise and a method of producing such a magnetic recording medium.

According to one aspect of the present invention, there is provided a perpendicular magnetic recording medium comprising a nonmagnetic intermediate layer made of a CoCr alloy including an oxide of at least one element selected from a group consisting of Si, Ti, Ta, Cr and Co, wherein the CoCr alloy further includes at least one element selected from a group consisting of Pt, Ta, Cu, Ru and B; and a magnetic layer, disposed above the nonmagnetic intermediate layer, and made of a CoCrPt alloy including an oxide of at least one element selected from a group consisting of Si, Ti, Ta, Cr and Co. According to the perpendicular magnetic recording medium of the present invention, it is possible to reduce the medium noise.

According to one aspect of the present invention, there is provided a method of producing a magnetic recording medium having a magnetic recording layer disposed above a nonmagnetic intermediate layer, comprising forming the nonmagnetic intermediate layer by a first sputtering using a first target made of an oxide material; and supplying oxygen gas or carbon dioxide gas during the first sputtering in order to suppress a state where an oxygen supply becomes insufficient due to separation of oxygen atoms from the oxide material at a time of plasma generation. According to the method of producing the magnetic recording medium of the present invention, it is possible to reduce the medium noise.

According to one aspect of the present invention, there is provided a method of producing a magnetic recording medium having a magnetic recording medium disposed above a nonmagnetic intermediate layer, comprising providing a target in which a plurality of oxide materials are mixed; and forming the nonmagnetic intermediate layer by a sputtering using the target in order to suppress a state where an oxygen supply becomes insufficient due to separation of oxygen atoms from the oxide material at a time of plasma generation, wherein the plurality of oxide materials include first metal atoms mainly forming the oxide, and second metal atoms forming the oxide for supplying the oxygen, and the second metal atoms have a low oxygen affinity with respect to the first metal atoms. According to the method of producing the magnetic recording medium of the present invention, it is possible to reduce the medium noise.

Other objects and further features of the present invention will be apparent from the following detailed description when read in conjunction with the accompanying drawings.

### BRIEF DESCRIPTION OF THE DRAWINGS

FIG. 1 is a cross sectional view showing an example of a magnetic recording medium that is produced in a first embodiment of the present invention.

FIG. 2 is a diagram showing a change in coercivity caused by addition of oxygen to a CoCrPt oxide.

FIG. 3 is a diagram showing a gradient of a magnetization curve caused by the addition of oxygen to the CoCrPt oxide.

FIG. 4 is a diagram showing a change in coercivity caused by addition of oxygen to a CoCr oxide.

FIG. 5 is a diagram showing a gradient of a magnetization curve caused by the addition of oxygen to the CoCr oxide.

FIG. 6 is a diagram showing a change in coercivity caused by addition of carbon dioxide to a CoCr oxide.

FIG. 7 is a diagram showing a gradient of a magnetization curve caused by the addition of carbon dioxide to the CoCr oxide.

FIG. 8 is a diagram showing compositions of a granular target.

FIG. 9 is a diagram for explaining magnetic characteristics of samples.

FIG. 10 is a diagram showing a change in coercivity with respect to a product of a magnetic layer thickness and saturation magnetic flux density.

FIG. 11 is a diagram showing a change in magnetization reversal field with respect to the product of the magnetic recording layer thickness and the saturation magnetic flux density. and

FIG. 12 is a diagram showing a change in gradient of a magnetization curve with respect to the product of the magnetic layer thickness and the saturation magnetic flux density.

### DESCRIPTION OF THE PREFERRED EMBODIMENTS

According to one aspect of the present invention, oxygen gas or carbon dioxide gas is supplied when forming at least one of a magnetic recording layer and a nonmagnetic intermediate layer of a magnetic recording medium by sputtering which uses a target made of an oxide material. As a result, it is possible to suppress a state where an oxygen supply becomes insufficient due to oxygen atoms separating from the oxide material at the time of the plasma generation, and to prevent the oxygen loss from occurring in at least one of the magnetic recording layer and the nonmagnetic intermediate layer that are formed. Consequently, it is possible to reduce the medium noise.

A gas partial pressure of the oxygen gas or carbon dioxide gas that is supplied when carrying out the sputtering is preferably in a range of approximately 0.01 Pa to approximately 0.1 Pa. In addition, when Ar mixture gas is used as the sputtering gas, the concentration of the Ar mixture gas is preferably in a range of approximately 0.004% to approximately 20%.

When carrying out the sputtering using the target made of the oxide material, it is possible to use a target in which a plurality of oxide materials are mixed, instead of supplying the oxygen gas or the carbon dioxide gas, in order to suppress the state where the oxygen supply becomes insufficient due to the oxygen atoms separating from the oxide material at the time of the plasma generation. In this case, the plurality of oxide materials include metal atoms mainly forming the oxide, and metal atoms forming the oxide for supplying the oxygen. The latter metal atoms desirably have a low oxygen affinity with respect to the former metal atoms, and desirably do not have excessive effects on the magnetic characteristics when forming the magnetic recording layer.

Next, a description will be given of each embodiment of the magnetic recording medium and the method producing the magnetic recording according to the present invention, by referring to the drawings.

### First Embodiment

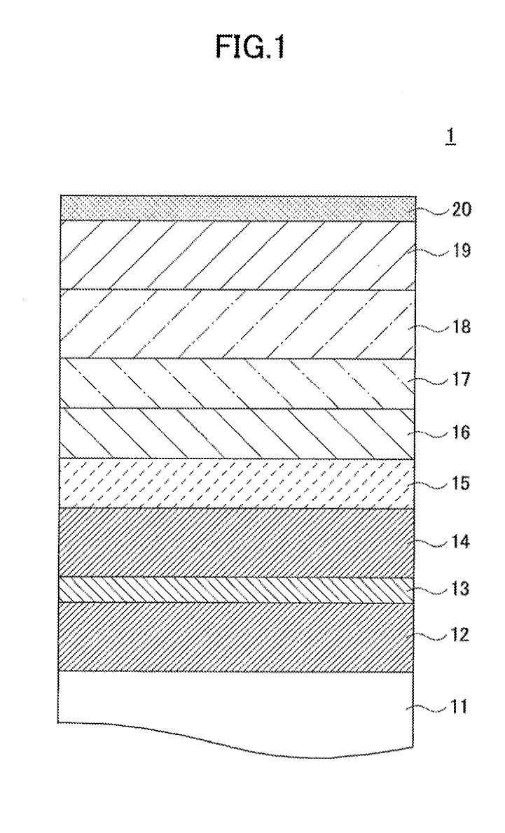

First, a description will be given of a method of producing the magnetic recording medium in a first embodiment of the present invention, by referring to FIGS. 1 through 7. In this embodiment, the present invention is applied to a method of producing a perpendicular magnetic recording medium employing the perpendicular magnetic recording technique.

FIG. 1 is a cross sectional view showing the example of the magnetic recording medium that is produced in the first embodiment of the present invention. A perpendicular magnetic recording medium 1 shown in FIG. 1 has a stacked structure including a nonmagnetic substrate 11. A first soft magnetic underlayer 12, a nonmagnetic underlayer 13, a second soft magnetic underlayer 14, a Ni alloy intermediate layer 15, a first nonmagnetic intermediate layer 16, a second nonmagnetic intermediate layer 17, a first magnetic layer 18, a second magnetic layer 19 and a protection layer 20 that are successively stacked on the nonmagnetic substrate 11.

The nonmagnetic substrate 11 is made of a nonmagnetic material such as Al, Al alloys and glass. The surface of the nonmagnetic substrate 11 may or may not be textured.

For example, the first and second soft magnetic underlayers 12 and 14 are made of Co alloys, Fe alloys or CoFe alloys, and have a thickness of approximately 10 nm to approximately 30 nm. It is not essential for the first and second soft magnetic underlayers 12 and 14 to be made of the same material or the same composition. For example, the nonmagnetic underlayer 13 is made of Ru or Ru alloys having at least one element selected from a group consisting of Co, Cr, Ti, Mn and Mo, and has a thickness of approximately 0.1 nm to approximately 1 nm.

For example, the Ni alloy intermediate layer 15 is made of Ni alloys having at least one element selected from a group consisting of W, Cr, B, C, Mn and Ta, and has a thickness of approximately 5 nm to approximately 10 nm.

For example, the first nonmagnetic intermediate layer 16 is made of Ru or Ru alloys including at least one element selected from a group consisting of Co, Cr, Ti, Mn and Mo, and has a thickness of approximately 5 nm to approximately 30 nm. For example, the second nonmagnetic intermediate layer 17 is made of CoCr alloys including an oxide (SiO₂, TiO₂, Ta₂O₅, Cr₂O₃ and CoO) of one element selected from a group consisting of Si, Ti, Ta, Cr and Co, and has a thickness of approximately 1 nm to approximately 3 nm. the CoCr alloys may further include at least one element selected from a group consisting of Pt, Ta, Cu, Ru and B. The first and second nonmagnetic intermediate layers 16 and 17 form a nonmagnetic intermediate layer.

For example, the first magnetic layer 18 is made of CoCrPt alloys including an oxide (SiO₂, TiO₂, Ta₂O₅, Cr₂O₃ and CoO) of one element selected from a group consisting of Si, Ti, Ta, Cr and Co, and has a thickness of approximately 5 nm to approximately 20 nm. For example, the second magnetic layer 19 is made of CoCrPt alloys or, CoCrPt alloys including at least one element selected from a group consisting of B, Cu, Ta and Nb, and has a thickness of approximately 5 nm to approximately 10 nm. The first and second magnetic layers 18 and 19 form a recording layer of the perpendicular magnetic recording medium 1.

The protection layer 20 may be formed by any known material suited for protecting the recording layer of the perpendicular magnetic recording medium 1. For example, the protection layer 20 is made of a C layer having a thickness of approximately 1 nm to approximately 5 nm, and a lubricant layer made of an organic lubricant and having a thickness of approximately 1 nm to approximately 3 nm.

Portions of the perpendicular magnetic recording medium 1, formed by the underlayers 12 through 14 and formed by the intermediate layers 15 and 16, are provided in order to improve the read and write characteristics of the perpendicular magnetic recording medium 1. Accordingly, each of the layers 12 through 16 may be appropriately provided depending on the performance required of the perpendicular magnetic recording medium 1 that is to be produced.

In FIG. 1, the perpendicular magnetic recording medium 1 includes both the second nonmagnetic intermediate layer 17 and the first magnetic layer 18, but only one of the second nonmagnetic intermediate layer 17 and the first magnetic layer 18 may be provided. In other words, if no first magnetic layer 18 is provided, the recording layer is formed solely of the second magnetic layer 19. On the other hand, if no second nonmagnetic intermediate layer 17 is provided, the nonmagnetic intermediate layer is formed solely of the first nonmagnetic intermediate layer 16.

Each of the layers 12 through 16 and 19 of the perpendicular magnetic recording medium 1 may be formed by a known method, such as sputtering.

In this embodiment, oxygen gas or carbon dioxide gas is supplied when forming at least one of the second nonmagnetic intermediate layer 17 and the first magnetic layer 18 by a sputtering using a target which is made of an oxide material. Hence, it is possible to suppress a state where the oxygen supply becomes insufficient due to oxygen atoms separating from the oxide material at the time of the plasma generation, and to prevent the oxygen loss from occurring in at least one of the second nonmagnetic intermediate layer 17 and the first magnetic layer 18 that are formed. The type of sputtering that is carried out is not limited to a particular type, and a DC sputtering, an RF sputtering, a magnetron sputtering or the like may be employed.

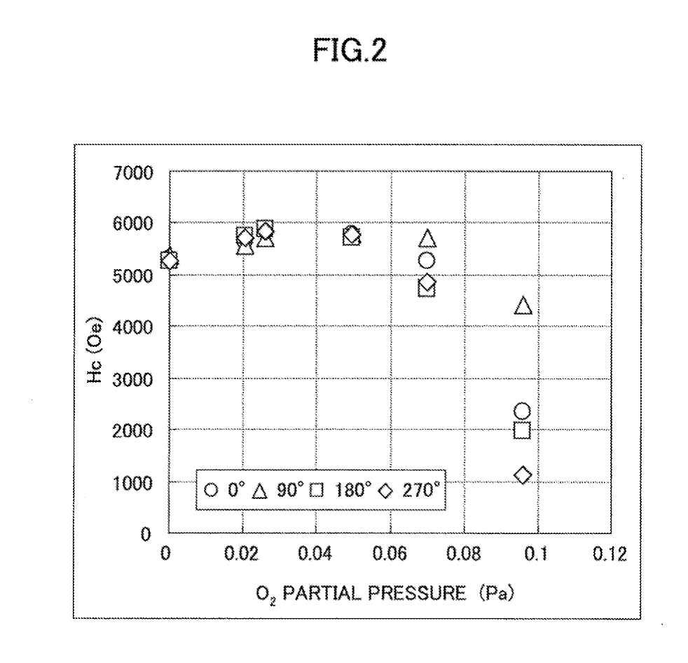

FIGS. 2 through 7 are diagrams showing measured results of a coercivity Hc and a gradient α′ of a magnetization curve that are measured by a known apparatus using the Kerr effect for each sample of the perpendicular magnetic recording medium 1 that is formed in this embodiment which supplies the oxygen gas or carbon dioxide gas when forming at least one of the second nonmagnetic intermediate layer 17 and the first magnetic layer 18 by the sputtering using the target which is made of an oxide material. FIGS. 2 through 7 show the measured results for the samples that are formed by supplying, to a sputtering apparatus (not shown) or a sputtering chamber (not shown), Ar gas and Ar mixture gas having approximately 3% oxygen gas or carbon dioxide mixed to Ar gas, when forming the second nonmagnetic intermediate layer 17 or the first magnetic layer 18 by the sputtering, and changing a gas partial pressure of the oxygen gas or a gas partial pressure of the carbon dioxide gas during the forming of the second nonmagnetic intermediate layer 17 or the first magnetic layer 18. An amount of the oxide in the target which is used to form each of the samples is 6 mol % in the case of the target used to form the second nonmagnetic intermediate layer 17 by adding the oxygen gas or the carbon dioxide gas, and is 8 mol % in the case of the target used to form the first magnetic layer 18 by adding the oxygen gas or the carbon dioxide gas.

The gradient α′ of the magnetization curve is an index which indicates an amount of change in the magnetization with respect to the magnetic field in the magnetization curve. The smaller the value of the gradient α′, the more gradual the magnetization curve, and the larger the gradient in a vicinity of the coercivity. In the perpendicular magnetic recording medium, the value of the gradient α′ is affected by the mutual interaction of the magnetic grains forming the recording layer, and if the magnetic material used for the recording layer is such that the magnetic grain sizes are approximately the same and the saturation magnetizations are approximately the same, the smaller the value of the gradient α′, the smaller the mutual interaction of the magnetic grains.

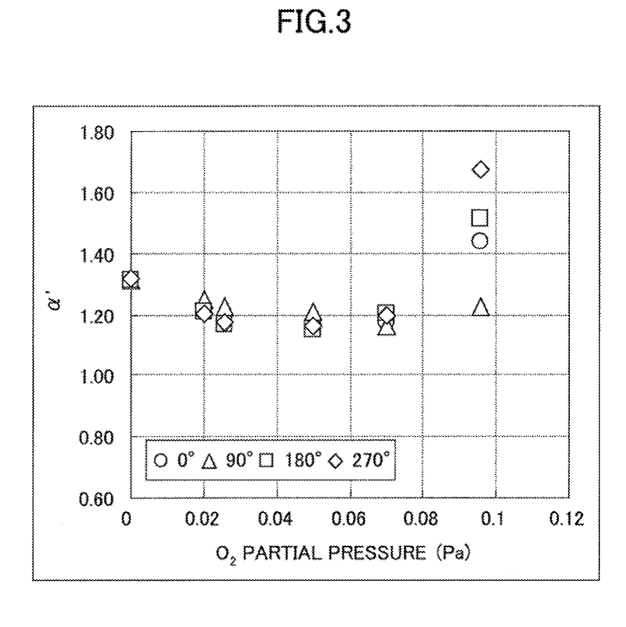

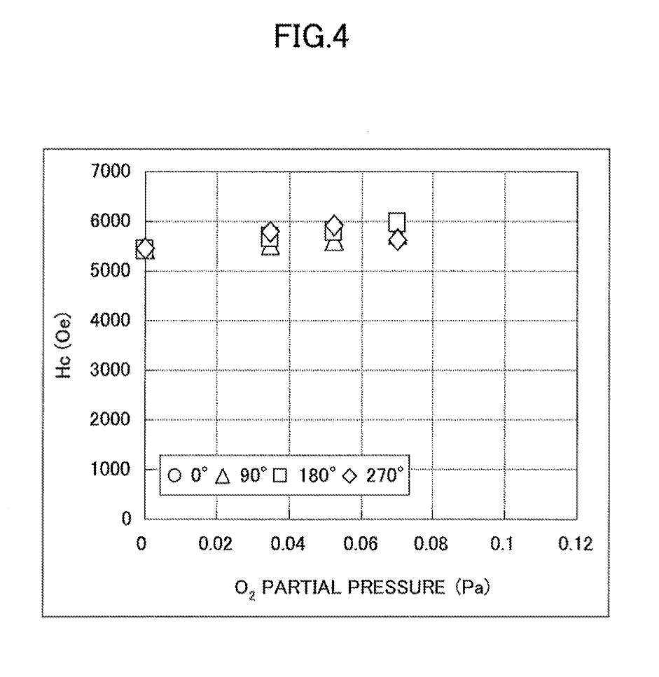

In FIGS. 2 through 7, data of 0° indicated by a symbol “◯”, data of 90° indicated by a symbol “Δ”, data of 180° indicated by a symbol “□”, and data of 270° indicated by a symbol “⋄” were respectively obtained by making measurements with a pitch of 90° at a radial position which is approximately 23 mm from a center of a disk-shaped sampled having a diameter of 2.5 inches. The measurements with the pitch that is a constant rotational angle were employed in order to enable evaluation of a distribution of the magnetic characteristics of the samples. The materials used for each of the layers 12 through 20 were selected as follows, and the thicknesses of the layers 12 through 20 were set in the ranges described above in conjunction with FIG. 1.
First Soft Magnetic Underlayer 12: Co Alloy
Nonmagnetic Underlayer 13: Ru
Second Soft Magnetic Underlayer 14: Co Alloy
Ni Alloy Intermediate Layer 15: NiCr
First Nonmagnetic Intermediate Layer 16: Ru
Second Nonmagnetic Intermediate Layer 17: CoCr Alloy (For FIGS. 2 and 3) Or, CoCr Alloy Including CoO (For FIGS. 4 through 7)
First Magnetic Layer 18: CoCrPt Alloy Including CoO (For FIGS. 2 and 3) Or, CoCrPt Alloy (For FIGS. 4 through 7)
Second Magnetic Layer 19: CoCrPt
Protection Layer 20: C

FIG. 2 is a diagram showing a change in the coercivity Hc (Oe) of the recording layer of the sample caused by the addition of oxygen to the CoCrPt oxide when forming the first magnetic layer 18. FIG. 3 is a diagram showing the gradient α′ of the magnetization curve of the recording layer of the sample caused by the addition of oxygen to the CoCrPt oxide when forming the first magnetic layer 18. The first magnetic layer 18 was formed at a layer forming pressure of 4 Pa. In this case, no oxygen addition was made to the CoCr oxide when forming the second nonmagnetic intermediate layer 17. The oxide of one element selected from a group consisting of Si, Ti, Ta, Cr and Co, used in this case, was Si oxide. FIGS. 2 and 3 show the data for the case where the oxide is SiO₂. In FIGS. 2 and 3, the abscissa indicates the gas partial pressure (Pa) of the oxygen (O₂) gas. In the case of metal oxides, the oxygen loss is introduced due to the effects of the oxide forming energy or the like, and for this reason, it is possible to obtain the effect of promoting the isolation of the magnetic grains by similarly supplying the oxygen gas when the element other than Si is selected from the above group.

It was confirmed that the change in the coercivity Hc (Oe) of the recording layer of the sample caused by the addition of carbon dioxide to the CoCrPt oxide when forming the first magnetic layer 18, and the gradient α′ of the magnetization curve of the recording layer of the sample caused by the addition of carbon dioxide to the CoCrPt oxide when forming the first magnetic layer 18, respectively show approximately the same tendencies as FIGS. 2 and 3 when the oxide similar to that used in FIGS. 2 and 3 are used with the layer forming pressure set to 4 Pa and no oxygen addition was made to the CoCr oxide when forming the second nonmagnetic intermediate layer 17.

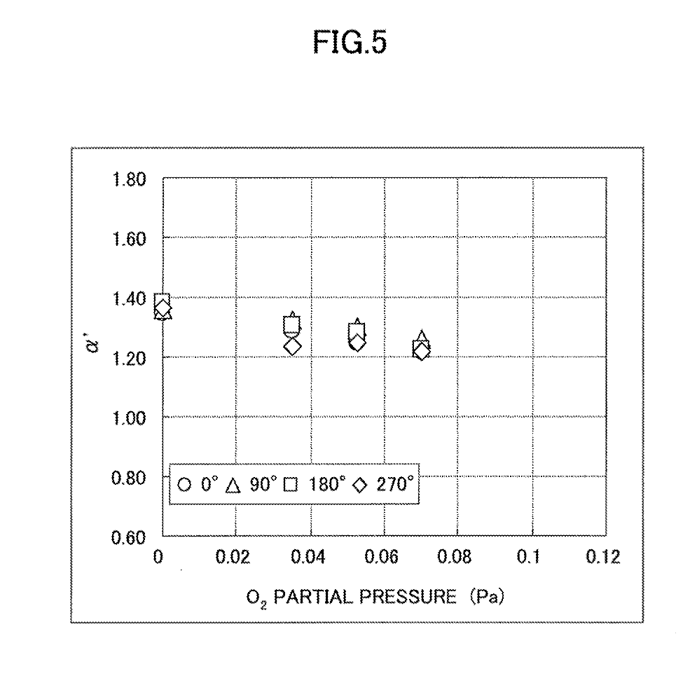

FIG. 4 is a diagram showing a change in the coercivity Hc (Oe) of the recording layer of the sample caused by addition of oxygen to the CoCr oxide when forming the second nonmagnetic intermediate layer 17. FIG. 5 is a diagram showing the gradient α′ of the magnetization curve of the recording layer of the sample caused by the addition of oxygen to the CoCr oxide when forming the second nonmagnetic intermediate layer 17. The second nonmagnetic intermediate layer 17 was formed at a layer forming pressure of 3 Pa. In this case, no oxygen addition was made to the CoCrPt oxide when forming the first magnetic layer 18. The oxide of one element selected from a group consisting of Si, Ti, Ta, Cr and Co, used in this case, was Ti oxide. FIGS. 4 and 5 show the data for the case where the oxide is TiO₂. In FIGS. 4 and 5, the abscissa indicates the gas partial pressure (Pa) of the oxygen (O₂) gas. In the case of metal oxides, the oxygen loss is introduced due to the effects of the oxide forming energy or the like as described above, and for this reason, it is possible to obtain the effect of promoting the isolation of the magnetic grains by similarly supplying the oxygen gas when the element other than Ti is selected from the above group. This was also confirmed from the similar effects that were obtained when the Si oxide was used for the second nonmagnetic intermediate layer 17.

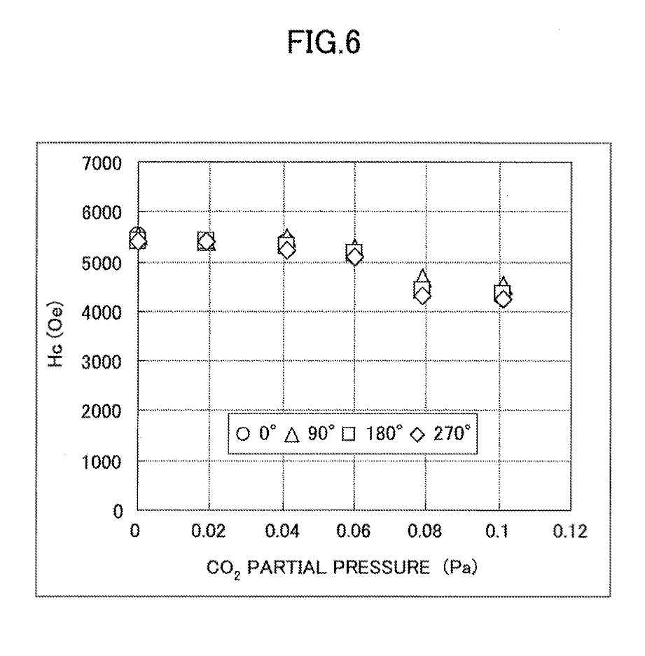

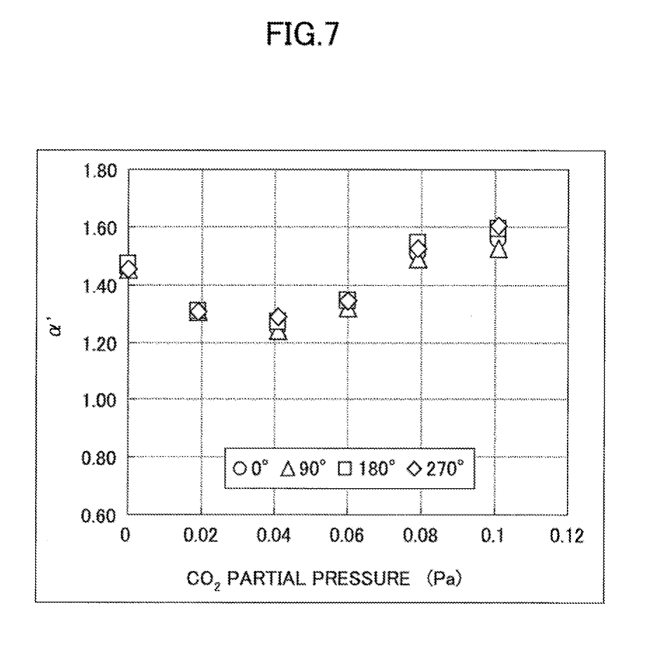

FIG. 6 is a diagram showing a change in the coercivity Hc (Oe) of the recording layer of the sample caused by addition of carbon dioxide to the CoCr oxide when forming the second nonmagnetic intermediate layer 17. FIG. 7 is a diagram showing the gradient α′ of the magnetization curve of the recording layer of the sample caused by the addition of carbon dioxide to the CoCr oxide when forming the second nonmagnetic intermediate layer 17. The second nonmagnetic intermediate layer 17 was formed at a layer forming pressure of 3 Pa. In this case, no oxygen addition was made to the CoCrPt oxide when forming the first magnetic layer 18. The oxide of one element selected from a group consisting of Si, Ti, Ta, Cr and Co, used in this case, was Si oxide. FIGS. 6 and 7 show the data for the case where the oxide is SiO₂. In FIGS. 6 and 7, the abscissa indicates the gas partial pressure (Pa) of the carbon dioxide (CO₂) gas. In the case of metal oxides, the oxygen loss is introduced due to the effects of the oxide forming energy or the like as described above, and for this reason, it is possible to obtain the effect of promoting the isolation of the magnetic grains by similarly supplying the oxygen gas when the element other than Si is selected from the above group.

From the measured results of FIGS. 2 through 7, it was confirmed that the gas partial pressure of the oxygen gas or the carbon dioxide gas that is supplied when forming the first magnetic layer 18 by sputtering using the target made of the oxide material is preferably in a range of approximately 0.01 Pa to approximately 0.1 Pa in which the coercivity Hc increases or the gradient α′ of the magnetization curve decreases and the effect of promoting the formation of the oxide by the supply of the oxygen can be confirmed, and more preferably in a range of approximately 0.02 Pa to approximately 0.06 Pa. In addition, it was confirmed that the gas partial pressure of the oxygen gas or the carbon dioxide gas that is supplied when forming the second nonmagnetic intermediate layer 17 by sputtering using the target made of the oxide material is preferably in a range of approximately 0.01 Pa to approximately 0.1 Pa in which the coercivity Hc increases or the gradient α′ of the magnetization curve decreases and the effect of promoting the formation of the oxide by the supply of the oxygen can be confirmed, and in which the in-plane distribution of the magnetic characteristic, such as the coercivity Hc, can be suppressed, and more preferably in a range of approximately 0.02 Pa to approximately 0.06 Pa.

Furthermore, it was confirmed that the concentration of the Cr mixture gas when two gas systems, namely, the Ar gas and the Ar mixture gas, are used as the sputtering gas, is preferably in a range of approximately 0.004% to approximately 20%, in order to set the gas partial pressure of the oxygen gas or the carbon dioxide to the above described range of approximately 0.01 Pa to approximately 0.1 Pa when forming the second nonmagnetic intermediate layer 17 or the first magnetic layer 18 by the sputtering using the target made of the oxide material.

It may be regarded that tendencies similar to those shown in FIGS. 1 through 7 will be obtainable when each of the layers 12 through 20 is made of the material selected from the corresponding group described above in conjunction with FIG. 1. In addition, the layer forming pressure when forming the second nonmagnetic intermediate layer 17 or the first magnetic layer 18 is not limited to the layer forming pressure described above. For example, the layer forming pressure when forming the second nonmagnetic intermediate layer 17 may be set to approximately 1 Pa to approximately 7 Pa, and the layer forming pressure when forming the first magnetic layer 18 may be set to approximately 2 Pa to approximately 7 Pa. Moreover, when forming the second nonmagnetic intermediate layer 17 or the first magnetic layer 18, it is desirable that the sputtering chamber is exhausted until the degree of vacuum within the sputtering chamber becomes approximately 1×10⁻⁴ Pa to approximately 1×10⁻⁶ Pa, and the sputtering is carried out at a power of approximately 100 W to approximately 700 W by supplying the sputtering gas.

If a sample is formed by supplying the oxygen gas or the carbon dioxide gas when forming both the second nonmagnetic intermediate layer 17 and the first magnetic layer 18 by a sputtering using a target made of an oxide material similar to that used in FIGS. 2 through 7, it may be regarded that this sample will at least show tendencies similar to those of FIGS. 2 through 7. This is because, if the oxygen or carbon dioxide is added to the oxide when forming the first magnetic layer 18, the first magnetic layer 18 will be formed by a granular layer in which the magnetic grains are satisfactorily isolated by the oxide, and the medium noise will be reduced thereby. Furthermore, if the oxygen or carbon dioxide is added to the oxide when forming the second nonmagnetic intermediate layer 17, the second nonmagnetic intermediate layer 17 will be formed by a granular layer in which the nonmagnetic grains are satisfactorily separated by the oxide, and this granular state of the second nonmagnetic intermediate layer 17 will be inherited to the first magnetic layer 18 which is formed on the second nonmagnetic intermediate layer 17, and the medium noise will be reduced thereby. Therefore, if both the second nonmagnetic intermediate layer 17 and the first magnetic layer 18 are formed by the sputtering using the target made of the oxide material similar to that used in FIGS. 2 through 7, it may be regarded that the granular state of the second nonmagnetic intermediate layer 17 will be inherited to the first magnetic layer 18 which is formed on the second nonmagnetic intermediate layer 17, to thereby further improve the isolation of the magnetic grains in the first magnetic layer 18 and further reduce the medium noise. This is also evident from the magnetic characteristics of the samples shown in FIG. 9 which will be described later.

### Second Embodiment

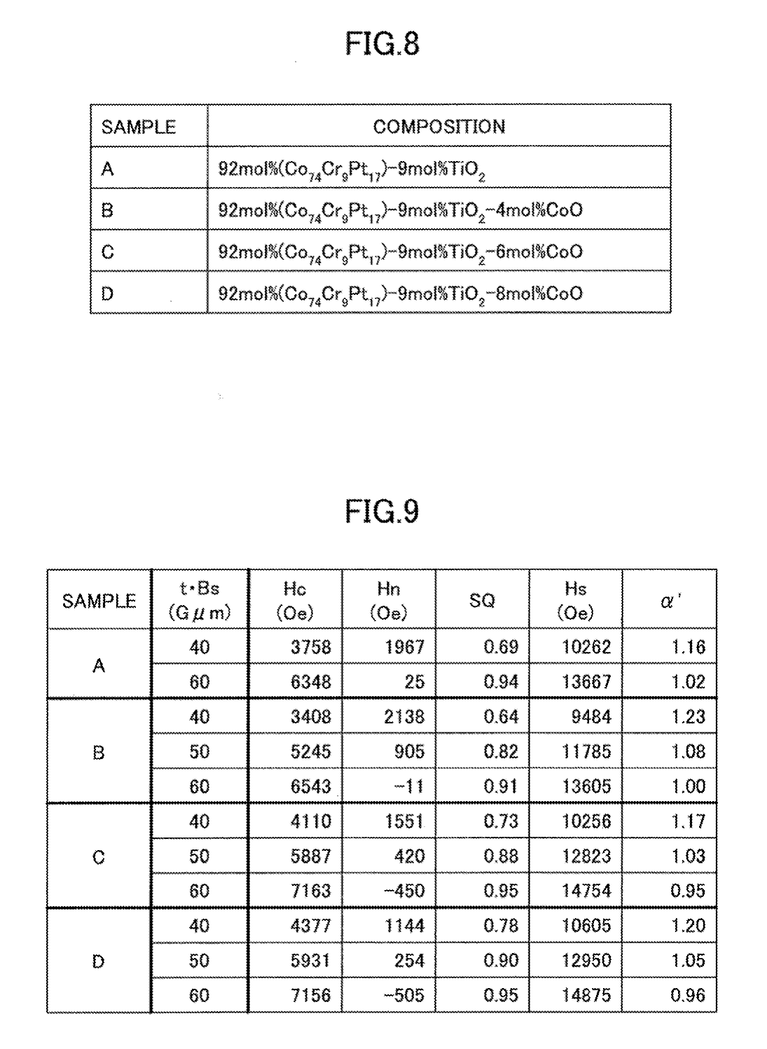

Next, a description will be given of the method of producing the magnetic recording medium in a second embodiment of the present invention, by referring to FIGS. 8 through 12. In this embodiment, the present invention is applied to a method of producing a perpendicular magnetic recording medium employing the perpendicular magnetic recording technique.

The cross section of an example of the magnetic recording medium produced in this embodiment is the same as that shown in FIG. 1, and description and illustration thereof will be omitted.

In this embodiment, each of the layers 12 through 16 and 19 of the perpendicular magnetic recording medium 1 may be formed by a known method, such as sputtering.

The target used may include a plurality of oxide materials mixed therein. In this case, it is desirable that the plurality of oxide materials include first metal atoms mainly forming the oxide, and second metal atoms forming the oxide for supplying the oxygen, where the second metal atoms have a low oxygen affinity with respect to the first metal atoms and do not excessively affect the magnetic characteristic when forming the recording layer. In other words, by using the target in which the first metal atoms mainly for forming the oxide is added with the second metal atoms having a higher oxide forming energy than (that is, more easily bonds to) the first metal atoms, it is possible to compensate for the oxygen loss in the second nonmagnetic intermediate layer 17 or the first magnetic layer 18 that is formed by emitting the decomposed (or separated) oxygen during the sputtering.

Hence, in this embodiment, the second nonmagnetic intermediate layer 17 is made of a CoCr alloy including an oxide (SiO₂, TiO₂, Ta₂O₅, Cr₂O₃ and CoO) of two or more elements selected from a group consisting of Si, Ti, Ta, Cr and Co, where the CoCr alloy further includes at least one element selected from a group consisting of Pt, Ta, Cu, Ru and B.

The first magnetic layer 18 is made of a CoCrPt alloy including an oxide (SiO₂, TiO₂, Ta₂O₅, Cr₂O₃ and CoO) of two or more elements selected from a group consisting of Si, Ti, Ta, Cr and Co.

Next, a description will be given of measured results with respect to 4 kinds of samples A through D of the perpendicular magnetic recording medium 1 that are formed in accordance with this embodiment, by using a granular target made of the oxide materials when forming the second nonmagnetic intermediate layer 17 and the first magnetic layer 18 by sputtering. The measured results were obtained by using pure Ar gas as the sputtering gas, and not supplying oxygen or carbon dioxide. FIG. 8 is a diagram showing compositions of the granular target used to form the samples A through D. As shown in FIG. 8, the granular target used to form the sample A is made of a single oxide material, and the granular targets used to form the samples B through D are made of 2 oxide materials.

The materials used for each of the layers 12 through 20 were selected as follows, and the thicknesses of the layers 12 through 20 were set in the ranges described above in conjunction with FIG. 1. Similarly to the first embodiment described above, the layer forming pressure was set to 3 Pa when forming the second nonmagnetic intermediate layer 17, and was set to 4 Pa when forming the first magnetic layer 18.
First Soft Magnetic Underlayer 12: Co Alloy
Nonmagnetic Underlayer 13: Ru
Second Soft Magnetic Underlayer 14: Co Alloy
Ni Alloy Intermediate Layer 15: NiCr
First Nonmagnetic Intermediate Layer 16: Ru
Second Nonmagnetic Intermediate Layer 17: CoCr Alloy Including TiO₂ (For Sample A) Or, CoCr Alloy Including TiO₂ and CoO (For Samples B, C and D)
First Magnetic Layer 18: CoCrPt Alloy Including TiO₂ (For Sample A) Or, CoCrPt Alloy Including TiO₂ and CoO (For Samples B, C and D)
Second Magnetic Layer 19: CoCrPt
Protection Layer 20: C

FIG. 9 is a diagram for explaining the magnetic characteristics of the samples A through D which were measured by a known measuring apparatus using the Kerr effect. In FIG. 9, t·Bs (Gμm) indicates a product of a thickness t of the recording medium (total thickness of the first and second magnetic layers 18 and 19) and the saturation magnetic flux density Bs of the recording layer, Hc (Oe) indicates the coercivity of the recording layer, Hn (Oe) indicates a nucleation field of the magnetic domain (or magnetic domain nucleus e) of the recording layer, Hs (Oe) denotes a magnetization reversal field, SQ indicates the squareness ratio, and α′ indicates the gradient of the magnetization curve.

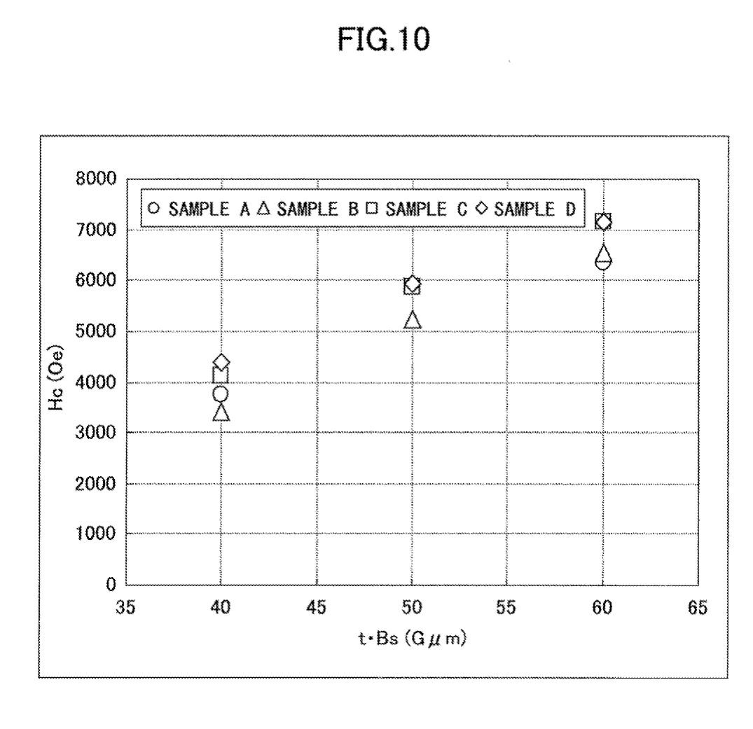

FIG. 10 is a diagram showing a change in the coercivity Hc with respect to the product t·Bs of the magnetic layer thickness t and the saturation magnetic flux density Bs. In FIG. 10, the ordinate indicates the coercivity Hc (Oe), and the abscissa indicates the product t·Bs (Gμm) of the magnetic layer thickness t and the saturation magnetic flux density Bs.

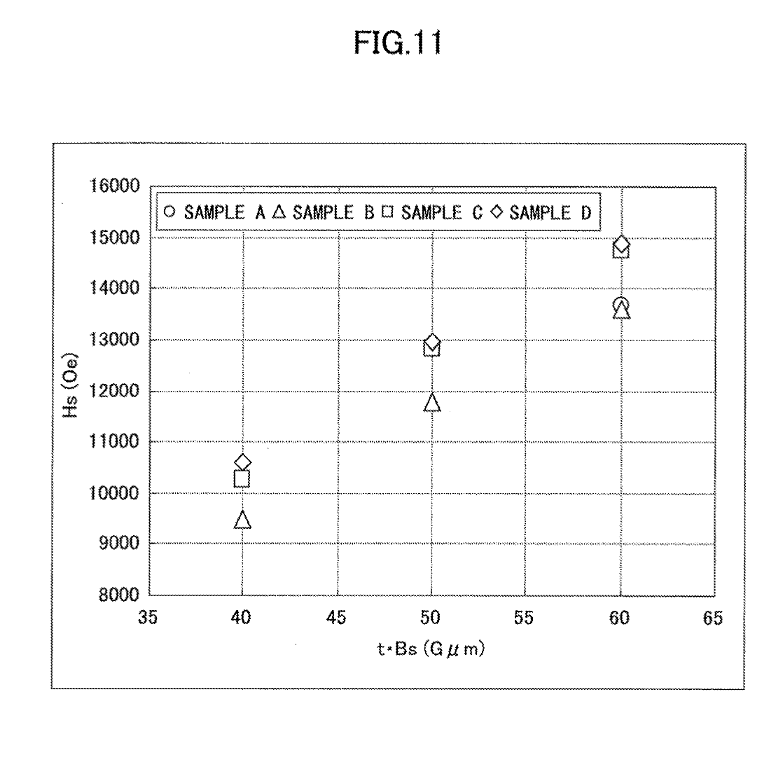

FIG. 11 is a diagram showing a change in the magnetization reversal field Hs with respect to the product t·Bs of the magnetic layer thickness t and the saturation magnetic flux density Bs. In FIG. 11, the ordinate indicates the magnetization reversal field Hs (Oe), and the abscissa indicates the product t·Bs (Gμm) of the magnetic layer thickness t and the saturation magnetic flux density Bs.

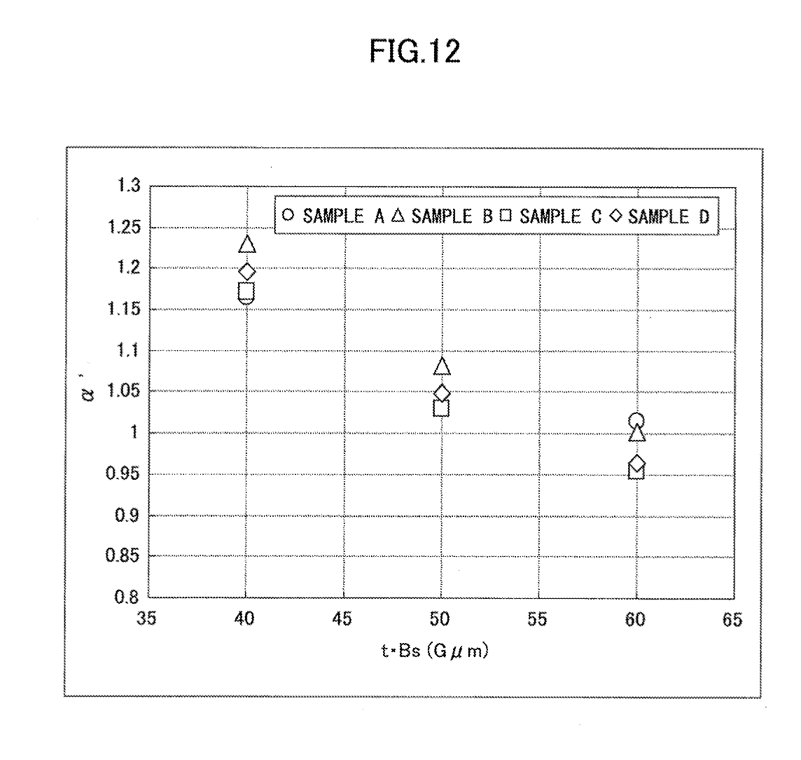

FIG. 12 is a diagram showing a change in the gradient α′ of the magnetization curve with respect to the product t·Bs of the magnetic layer thickness t and the saturation magnetic flux density Bs. In FIG. 12, the ordinate indicates the gradient α′ of the magnetization curve with respect to the product t·Bs (Gμm) of the magnetic layer thickness t and the saturation magnetic flux density Bs.

In FIGS. 10 through 12, symbols “◯” indicate the data of the sample A, symbols “Δ” indicate the data of the sample B, symbols “□” indicate the data of the sample C, and symbols “⋄” indicate the data of the sample D. As may be seen from FIGS. 10 through 12, it was confirmed that, compared to the sample A (corresponds to the first embodiment) for which the added oxide consists solely of TiO₂, the samples B, C and D for which the added oxides include CoO in addition to TiO₂ show even higher coercivities Hc. It may be regarded that the higher coercivities Hc are obtained in the samples B, C and D because, when the CoO is added in addition to TiO₂, the Co oxide having a relatively weak bonding strength with respect to the oxygen causes the oxygen separated during the sputtering to compensate for the oxygen loss of the TiO₂, to thereby promote the magnetic isolation of the magnetic grains.

When CoO is added to the oxides other than TiO₂ in the group of oxides described above or, the oxides other than CoO in the group of oxides described above are added to TiO₂, the magnetic characteristic can also be improved similarly to the samples B, C and D, by combining (or mixing) the oxides having different oxygen affinities. Co is particularly desirable as the element that is added to supply the oxygen to compensate for the oxygen loss.

The magnetic recording medium produced by each of the embodiments described above may be provided within a magnetic storage apparatus, such as a magnetic disk apparatus, which is provided with a head for recording signal on and reproducing signals from the magnetic recording medium. The basic structure of such a magnetic storage apparatus itself is known, and description and illustration thereof will be omitted.

This application claims the benefit of a Japanese Patent Application No.2007-309442 filed Nov. 29, 2007, in the Japanese Patent Office, the disclosure of which is hereby incorporated by reference.

Further, the present invention is not limited to these embodiments, but various variations and modifications may be made without departing from the scope of the present invention.

What is claimed is:

1. A perpendicular magnetic recording medium comprising:
a first nonmagnetic intermediate layer made of a CoCr alloy including an oxide of at least one element selected from a group consisting of Si, Ti, Ta, Cr and Co, wherein the CoCr alloy further includes at least one element selected from a group consisting of Pt, Ta, Cu, Ru and B; and
a first magnetic layer, disposed above the first nonmagnetic intermediate layer, and made of a CoCrPt alloy including an oxide of at least one element selected from a group consisting of Si, Ti, Ta, Cr and Co.

2. The perpendicular magnetic recording medium as claimed in claim 1, further comprising:
a second nonmagnetic intermediate layer made of Ru or an Ru alloy including at least one element selected from a group consisting of Co, Cr, Ti, Mn and Mo,
wherein the first nonmagnetic intermediate layer is provided on the second nonmagnetic intermediate layer.

3. The perpendicular magnetic recording medium as claimed in claim 1, further comprising:
a second magnetic layer, provided on the first magnetic layer, and made of a CoCrPt alloy or, a CoCrPt alloy including at least one element selected from a group consisting of B, Cu, Ta and Nb.

4. A method of producing a magnetic recording medium having a magnetic recording layer disposed above a nonmagnetic intermediate layer, comprising:
forming the nonmagnetic intermediate layer by a first sputtering using a first target made of an oxide material; and
supplying oxygen gas or carbon dioxide gas during the first sputtering in order to suppress a state where an oxygen supply becomes insufficient due to separation of oxygen atoms from the oxide material at a time of plasma generation.

5. The method of producing the magnetic recording medium as claimed in claim 4, further comprising:
forming the magnetic layer by a second sputtering using a second target made of an oxide material; and
supplying oxygen gas or carbon dioxide gas during the second sputtering in order to suppress a state where an oxygen supply becomes insufficient due to separation of oxygen atoms from the oxide material at a time of plasma generation.

6. The method of producing the magnetic recording medium as claimed in claim 5, wherein a gas partial pressure of the oxygen gas or the carbon dioxide gas supplied during the second sputtering is 0.01 Pa to 0.1 Pa.

7. The method of producing the magnetic recording medium as claimed in claim 5, wherein a gas partial pressure of the oxygen gas or the carbon dioxide gas supplied during the second sputtering is 0.02 Pa to 0.06 Pa.

8. The method of producing the magnetic recording medium as claimed in claim 5, wherein a concentration of Ar mixture gas which is used as a sputtering gas when carrying out the second sputtering is 0.04% to 20%.

9. The method of producing the magnetic recording medium as claimed in claim 4, wherein a gas partial pressure of the oxygen gas or the carbon dioxide gas supplied during the first sputtering is 0.01 Pa to 0.1 Pa.

10. The method of producing the magnetic recording medium as claimed in claim 4, wherein a gas partial pressure of the oxygen gas or the carbon dioxide gas supplied during the first sputtering is 0.02 Pa to 0.06 Pa.

11. The method of producing the magnetic recording medium as claimed in claim 4, wherein a concentration of Ar mixture gas which is used as a sputtering gas when carrying out the first sputtering is 0.04% to 20%.

12. A method of producing a magnetic recording medium having a magnetic recording medium disposed above a nonmagnetic intermediate layer, comprising:
providing a target in which a plurality of oxide materials are mixed; and
forming the nonmagnetic intermediate layer by a sputtering using the target in order to suppress a state where an oxygen supply becomes insufficient due to separation of oxygen atoms from the oxide material at a time of plasma generation,
wherein the plurality of oxide materials include first metal atoms mainly forming the oxide, and second metal atoms forming the oxide for supplying the oxygen, and the second metal atoms have a low oxygen affinity with respect to the first metal atoms.

13. The method of producing the magnetic recording medium as claimed in claim 12, wherein the nonmagnetic intermediate layer comprises:
a first nonmagnetic intermediate layer made of Ru or a Ru alloy including at least one element selected from a group consisting of Co, Cr, Ti, Mn and Mo; and
a second nonmagnetic intermediate layer, provided on the first nonmagnetic intermediate layer, and made of a CoCr alloy including an oxide of at least one element selected from a group consisting of Si, Ti, Ta, Cr and Co, where the CoCr alloy further includes at least one element selected from a group consisting of Pt, Ta, Cu, Ru and B.

14. The method of producing the magnetic recording medium as claimed in claim 13, wherein the oxide includes at least one oxide selected from a group consisting of SiO₂, TiO₂, Ta₂O₅, Cr₂O₃ and CoO.

15. The method of producing the magnetic recording medium as claimed in claim 13, wherein the magnetic recording medium employs a perpendicular magnetic recording technique.

16. The method of producing the magnetic recording medium as claimed in claim 12, wherein the magnetic layer comprises:
a first magnetic layer made of a CoCrPt alloy including an oxide of at least one element selected from a group consisting of Si, Ti, Ta, Cr and Co; and
a second magnetic layer, provided on the first magnetic layer, and made of a CoCrPt alloy or, a CoCrPt alloy including at least one element selected from a group consisting of B, Cu, Ta and Nb.

17. The method of producing the magnetic recording medium as claimed in claim 16, wherein the oxide includes at least one oxide selected from a group consisting of SiO₂, TiO₂, Ta₂O₅, Cr₂O₃ and CoO.

18. The method of producing the magnetic recording medium as claimed in claim 16, wherein the magnetic recording medium employs a perpendicular magnetic recording technique.
